(19) United States
(12) Patent Application Publication
(10) Pub. No.: US 2026/0150582 A1
(43) Pub. Date: May 28, 2026

(54) ELECTRONIC DEVICE AND METHOD FOR FABRICATING THE SAME

(71) Applicant: SK hynix Inc., Gyeonggi-do (KR)

(72) Inventors: Keo Rock CHOI, Gyeonggi-do (KR); Jeong Myeong KIM, Gyeonggi-do (KR); Cha Deok DONG, Gyeonggi-do (KR); Bo Kyung JUNG, Gyeonggi-do (KR)

(21) Appl. No.: 19/239,962

(22) Filed: Jun. 17, 2025

(30) Foreign Application Priority Data
Nov. 27, 2024 (KR) 10-2024-0171631

(51) Int. Cl. H10N 50/10; H10N 50/01

(52) U.S. Cl. CPC H10N 50/10; H10N 50/01

(57) ABSTRACT

A method for fabricating an electronic device includes forming a material layer suitable for forming an etched layer over a first substrate; forming a hard mask layer over a second substrate; bonding the first substrate and the second substrate with each other in such a manner that the material layer and the hard mask layer face each other; removing the second substrate from an upper portion of the hard mask layer; and forming an etched layer pattern by performing an etching process with the hard mask layer used as an etching barrier.

### CROSS-REFERENCE TO RELATED APPLICATIONS

The present application claims priority under 35 U.S. C 119(a) to Korean Patent Application No. 10-2024-0171631, filed on Nov. 27, 2024, which is incorporated herein by reference in its entirety.

### BACKGROUND

### 1. Field

Embodiments of the present disclosure relate generally to semiconductor technology, and, more particularly, to a memory circuit or device, and its applications in electronic devices.

### 2. Description of the Related Art

Recent demands for miniaturization, low power consumption, high performance, and diversification of electronic devices require semiconductor devices capable of storing data in various electronic devices, such as computers, portable communication devices and the like, and researchers and the industry are studying to develop such semiconductor devices. Such semiconductor devices include semiconductor devices capable of storing data by using the characteristics of switching between different resistance states according to an applied voltage or current, such as a Resistive Random Access Memory (RRAM), a Phase-change Random Access Memory (PRAM), a Ferroelectric Random Access Memory (FRAM), a Magnetic Random Access Memory (MRAM), an E-fuse and the like.

### SUMMARY

Embodiments of the present disclosure are directed to solving a problem of deteriorating operation characteristics of an electronic device including a Magnetic Tunnel Junction (MTJ) structure or a selection element, which may occur when a high-temperature process is performed after a Magnetic Tunnel Junction (MTJ) or a selection element is deposited, while securing a process margin by forming a hard mask layer through a high-temperature process in a process of fabricating an electronic device including an MTJ structure or a selection element.

In accordance with an embodiment of the present disclosure, an electronic device includes an etched layer disposed over a substrate and having a vertical profile; a hard mask pattern disposed over the etched layer; and a bonding layer disposed between the etched layer and the hard mask pattern and including a dielectric material, wherein the hard mask pattern includes a material having an etching selectivity with respect to the etched layer.

In accordance with another embodiment of the present disclosure, a method for fabricating an electronic device includes forming a material layer suitable for forming an etched layer over a first substrate; forming a hard mask layer over a second substrate; bonding the first substrate and the second substrate with each other in such a manner that the material layer and the hard mask layer face each other; removing the second substrate from an upper portion of the hard mask layer; and forming an etched layer pattern by performing an etching process with the hard mask layer used as an etching barrier.

In accordance with yet another embodiment of the present disclosure, a method for fabricating an electronic device includes forming a material layer suitable for forming a selection element over a third substrate; forming a hard mask layer over a fourth substrate; bonding the third substrate and the fourth substrate with each other in such a manner that the material layer and the hard mask layer face each other; removing the fourth substrate from an upper portion of the hard mask layer; and forming a selection element pattern having a vertical profile by performing an etching process with the hard mask layer used as an etching barrier.

These and other features and advantages of the embodiments of the present disclosure will become apparent to those skilled in the art from the following detailed description in conjunction with the following drawings.

### BRIEF DESCRIPTION OF THE DRAWINGS

FIGS. 1A and 1B are cross-sectional views illustrating an electronic device in accordance with an embodiment of the present disclosure.

FIGS. 2A to 2E are cross-sectional views illustrating an electronic device and a method for fabricating the same in accordance with another embodiment of the present disclosure.

FIGS. 3A to 3E are cross-sectional views illustrating an electronic device and a method for fabricating the same in accordance with yet another embodiment of the present disclosure.

### DETAILED DESCRIPTION

Hereinafter, the various embodiments of the present disclosure will be described in detail with reference to the attached drawings.

Various embodiments of the present disclosure will be described below in more detail with reference to the accompanying drawings. The embodiments may, however, be embodied in different forms and should not be construed as limited to the embodiments set forth herein. Rather, these embodiments are provided so that this disclosure will be thorough and complete, and will fully convey the scope of the present disclosure to those skilled in the art. Throughout this disclosure, like reference numerals refer to like parts throughout the various figures and embodiments of the present disclosure.

The drawings are not necessarily to scale and in some instances, proportions may have been exaggerated to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

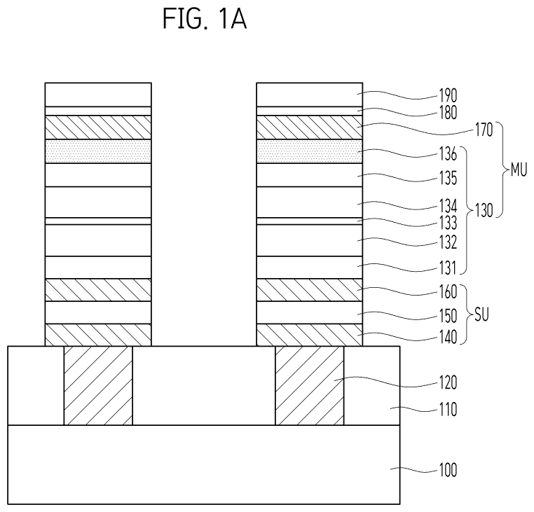

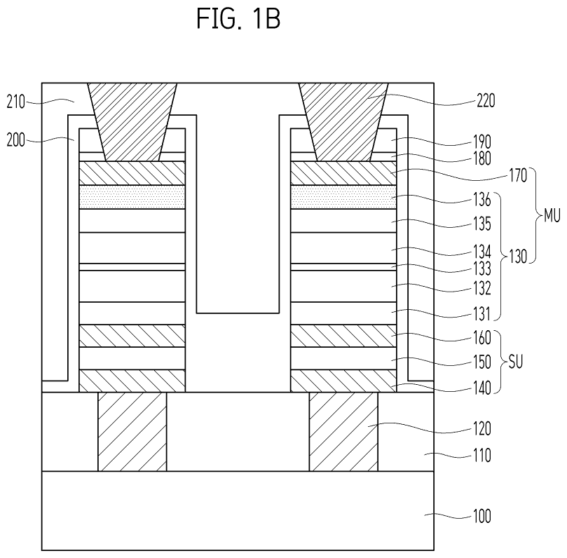

FIGS. 1A and 1B are cross-sectional views illustrating an electronic device having an etched layer, such as a variable resistance layer and a selection element unit SU, in accordance with an embodiment of the present disclosure.

Referring to FIG. 1A, after a first inter-layer dielectric layer 110 is formed over a substrate 100, a lower contact plug 120 may be formed to pass through the first inter-layer dielectric layer 110 to be operatively coupled to a portion of the substrate 100. The lower contact plug 120 may contact the substrate 100. A plurality of lower contact plugs 120 may be formed spaced apart from each other.

Subsequently, a selection element unit SU may be formed over the contact plug 120. The selection element unit SU may include a lower electrode layer 140, a selection element layer 150, and an intermediate electrode layer 160. The lower electrode layer 140 may contact the top surface of the lower contact plug 120. The selection element unit 150 and the intermediate electrode layer 160 may be disposed sequentially over the lower electrode layer 140. Subsequently, a variable resistance element 130 may be formed over the selection element unit SU. The variable resistance element 130 may include a lower layer 131, a free layer 132, a tunnel barrier layer 133, a fixed layer 134, a magnetic compensation layer 135, and a capping layer 136 that are stacked over the first inter-layer dielectric layer 110 and the lower contact plug 120. The selection element unit SU and the variable resistance element 130 may have a vertical profile.

The performance of the MTJ structure included in the variable resistance element 130 may be optimized when the layers such as the free layer 132, the tunnel barrier layer 133, and the fixed layer 134 are precisely patterned and maintain the vertical profile. However, in order to maintain the characteristics of the MTJ structure, only a low-temperature process of approximately 300° C. or lower may be performed, which has limitations in forming a high-quality ion beam etched (IBE) hard mask HM. This makes it difficult to form an MTJ structure with a vertical profile, and there is a limitation in the fabrication of a high-density MRAM. According to an embodiment, of the present disclosure a method for forming a high-quality hard mask is provided which is required for an IBE etching process with a high-temperature process exceeding approximately 300° C. using a wafer bonding technique. Also, by ensuring that the selection element unit SU has a vertical profile, space efficiency may be maximized thus realizing a high-density integrated circuit. Also, since the selection element unit SU is formed to have a clear and uniform boundary, leakage current may be minimized. Also, the performance and reliability of the element may be improved by enabling precise alignment between the layers in a multi-layer structure. In this way, an electronic device having a selection element unit SU and a memory unit MU with a vertical profile as illustrated in FIG. 1A is provided.

The selection element unit SU may include a lower electrode layer 140, a selection element layer 150, and an intermediate electrode layer 160. The memory unit MU may include an intermediate electrode layer 160, a variable resistance element 130, and an upper electrode layer 170. Thus, the intermediate electrode layer 160 may be shared by the selection element unit SU and the memory unit MU.

The lower electrode layer 140 and the upper electrode layer 170 may be disposed at both ends of a memory cell, that is, at the bottom end and the top end of a memory cell, respectively, and may function to transfer a voltage or current that is required for the operation of the memory cell MC. The intermediate electrode layer 160 may function to electrically connect the selection element layer 150 and the variable resistance element 130 to each other while physically separating them from each other. The lower electrode layer 140, the intermediate electrode layer 160, or the upper electrode layer 170 may be formed from various conductive materials including, for example, metals such as platinum (Pt), tungsten (W), aluminum (Al), copper (Cu), tantalum (Ta), titanium (Ti) and the like, metal nitrides such as titanium nitride (TiN), tantalum nitride (TaN) and the like, and combinations thereof. Also, the lower electrode layer 140, the intermediate electrode layer 160, or the upper electrode layer 170 may include a carbon electrode.

A bonding layer 180 and a hard mask pattern 190 may be formed over the upper electrode layer 170 according to the substrate bonding and separation processes described below.

The selection element layer 150 may function to prevent current leakage that may occur between the memory cells MC that share a first conductive line or a second conductive line, while controlling the access to the variable resistance element 130. To this end, the selection element layer 150 may have the threshold switching characteristics of blocking the current or holding the current to hardly flow when the level of the voltage supplied to the upper and lower ends of the selection element layer 150 is below a predetermined threshold voltage level, and then letting the current to rapidly flow at a voltage level which is equal to or higher than the threshold voltage level. The selection element layer 150 may be turned on at the threshold voltage level or higher and may be turned off below the threshold voltage level. For example, the selection element layer 150 may include a dielectric material into which a dopant is implanted.

A Magnetic Tunnel Junction (MTJ) structure may include a free layer 132 having a changeable magnetization direction, a tunnel barrier layer 133 allowing electron tunneling according to the applied voltage or current, and a fixed layer 134 having a fixed magnetization direction. The lower layer 131 may be disposed below the MTJ structure and help efficiently implant spin into the free layer 132, which may improve the switching characteristics of the MTJ structure. The lower layer 131 may contribute to increasing the magnetization stability of the free layer 132, and may increase the reliability of the entire structure by enhancing the mechanical and electrical connection between the free layer 132 and the tunnel barrier layer 133. The magnetic compensation layer 135 may perform the function of offsetting or reducing the influence of a stray magnetic field that is formed by the fixed layer 134. The magnetic compensation layer 135 may reinforce the magnetization of the fixed layer 134 to help prevent the magnetization direction of the fixed layer 134 from changing due to an external magnetic field or temperature change, and may enhance the magnetic anisotropy of the fixed layer 134 to allow the fixed layer 134 to maintain a more stable magnetization state. The capping layer 136 may function to protect the layers disposed lower and below the capping layer 136 during the patterning process for forming the variable resistance element 130 and may also connect the variable resistance element 130 to the constituent element over the variable resistance element 130. To this end, the capping layer 136 may be formed of material such as a metal, which is a low resistance material. The capping layer 136 may protect the MTJ structure from the external environment to prevent it from being oxidized, thus maintaining the lifespan and performance of the MTJ structure.

Referring to FIG. 1B, after the spacer 200 is formed based on the process result of FIG. 1A, a second inter-layer dielectric layer 210 may be formed over the spacer 200. The spacer 200 may be formed by depositing a dielectric layer into the process result of FIG. 1A through a Chemical vapor deposition (CVD) process or an Atomic Layer Deposition (ALD) process, and then performing an anisotropic etching process to have a uniform dielectric layer remain on the side and top surfaces of the structure of FIG. 1A.

Subsequently, an upper contact plug 220 may be formed by selectively etching the second inter-layer dielectric layer 210, the spacer 200, the hard mask pattern 190, and the bonding layer 180 to form a hole that exposes the upper surface of the upper electrode layer 170, and then filling the hole with a conductive material. The spacer 200 may be a thin and narrow dielectric layer that is formed on the side of the variable resistor element to protect the surface and side of the variable resistor element and prevent damage or contamination during a subsequent process.

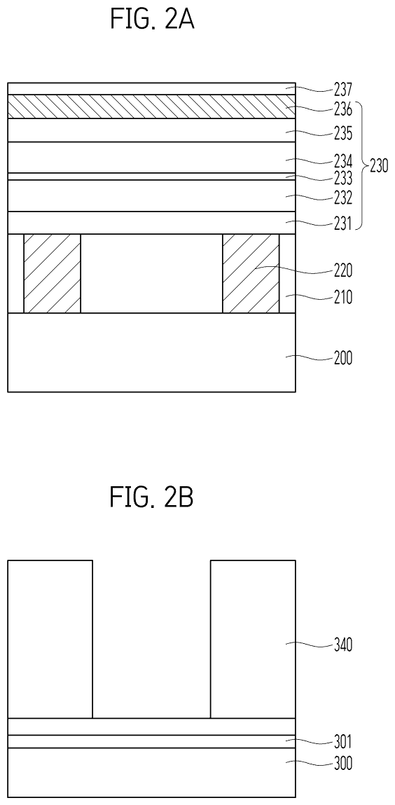

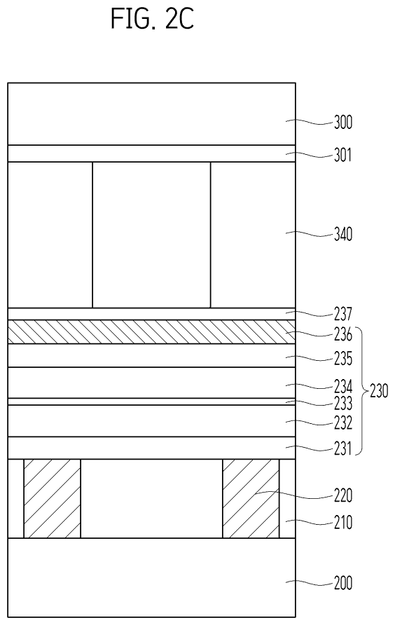

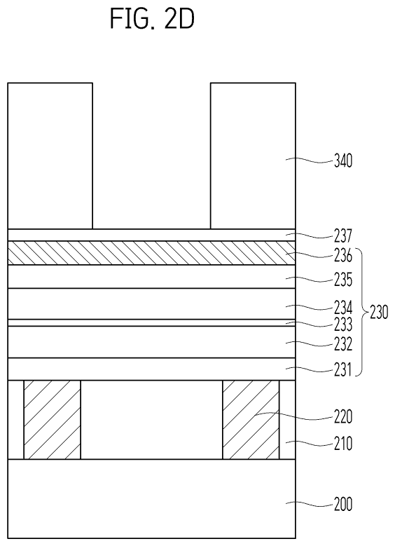

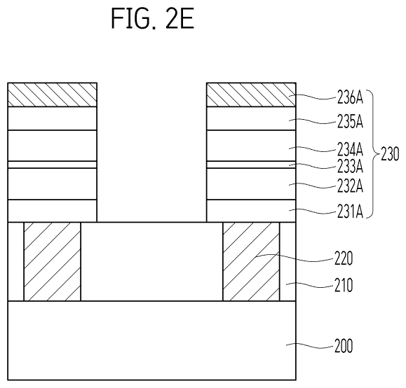

FIGS. 2A to 2E are cross-sectional views illustrating an electronic device and a fabrication method thereof in accordance with an embodiment of the present disclosure.

First, the fabrication method will be described.

Referring to FIG. 2A, a first substrate 200 is provided. The first substrate 200 may include a required predetermined structure, such as, for example, one or more switching elements (not shown). For example, the switching element may be operatively coupled to a variable resistance element, which will be described below, to control whether to supply a current or voltage to the variable resistance element or not, and the switching element may include, for example, a transistor, a diode, and the like. One end of the switching element may be electrically connected to a lower contact plug 220, which is described below, and the other end may be electrically connected to an interconnection which is not illustrated, for example, a source line. The first substrate 200 may be a semiconductor substrate formed of bulk silicon, bulk silicon-germanium, or a semiconductor substrate where a silicon or silicon-germanium epitaxial layer is formed over the bulk silicon or bulk silicon-germanium. Also, the first substrate 200 may include one semiconductor structure selected from the group including silicon-on-sapphire (SOS), silicon-on-insulator (SOI), thin film transistor (TFT), doped semiconductors and undoped semiconductors, a silicon epitaxial layer supported by a substrate semiconductor, and the like.

Although not illustrated, the first substrate 200 may include a substrate that is obtained after a predetermined process, such as a process of forming a well, an isolation layer, a gate, a source/drain, a plurality of contacts, interconnections and the like. The first substrate 200 may further include an interconnection in addition to a driving element, i.e., a peripheral circuit unit.

Subsequently, a first inter-layer dielectric layer 210 is formed over the first substrate 200. Then, a lower contact plug 220 is formed that passes through the first inter-layer dielectric layer 210 to be electrically connected to a portion of the first substrate 200, for example, one end of a switching element. The first inter-layer dielectric layer 210 may include various dielectric materials, such as silicon oxide, silicon nitride, or a combination thereof. The lower contact plug 220 may be formed by first selectively etching the first inter-layer dielectric layer 210 to form a contact hole that exposes a portion of the first substrate 200, then depositing a conductive material having a sufficient thickness to fill the contact hole, and performing a planarization process, for example, Chemical Mechanical Polishing (CMP), until the upper surface of the first inter-layer dielectric layer 210 is exposed. The lower contact plug 220 may include a conductive material having excellent filling characteristics and high electrical conductivity, such as tungsten (W), tantalum (Ta), or titanium nitride (TiN). As shown in FIG. 2A, a plurality of lower contact plugs 220 may be formed simultaneously.

Subsequently, material layers for forming a variable resistance element, such as a lower layer 231, a free layer 232, a tunnel barrier layer 233, a fixed layer 234, a magnetic compensation layer 235, and a capping layer 236, may be formed over the first inter-layer dielectric layer 210 and the lower contact plug 220.

The free layer 232 may store different data by having a changeable magnetization direction. The free layer 232 may also be referred to as a storage layer. The fixed layer 234 may be a layer that may be contrasted to the magnetization direction of the free layer 232 by having a fixed magnetization direction. The fixed layer 234 may also be referred to as a reference layer. The free layer 232 and the fixed layer 234 may have a single-layer structure or a multi-layer structure including a ferromagnetic material. For example, the free layer 232 and the fixed layer 234 may include an alloy mainly including Fe, Ni or Co, such as an a Fe—Pt alloy, a Fe—Pd alloy, a Co—Pd alloy, a Co—Pt alloy, a Fe—Ni—Pt alloy, a Co—Fe—Pt alloy, a Co—Ni—Pt alloy, a Fe—Pd alloy, a Co—Pd alloy, a Co—Pt alloy, a Fe—Ni—Pt alloy, a Co—Fe—Pt alloy, a Co—Ni—Pt alloy, a Co—Fe—B alloy and the like, or the free layer 232 and the fixed layer 234 may include a stacked structure such as Co/Pt or Co/Pd. The magnetization directions of the free layer 232 and the fixed layer 234 may be perpendicular or substantially perpendicular to the layer surface. The magnetization direction of the free layer 232 may vary between the direction from top to bottom and the direction from bottom to top, and the magnetization direction of the fixed layer 234 may be fixed in the direction from top to bottom or the direction from bottom to top. This change in the magnetization direction of the free layer 232 may occur due to spin transfer torque. The relative positions of the free layer 232 and the fixed layer 234 may vary diversely with the tunnel barrier layer 233 interposed therebetween. For example, unlike the embodiment of FIG. 2A, in other embodiments (not shown), the fixed layer 234 may be disposed below the tunnel barrier layer 233, and the free layer 232 may be disposed over the tunnel barrier layer 233.

The tunnel barrier layer 233 may enable tunneling of electrons between the free layer 232 and the fixed layer 234 during a write operation that changes the resistance state of the variable resistance element, thereby changing the magnetization direction of the free layer 232. The tunnel barrier layer 233 may include a dielectric oxide, such as MgO (magnesium oxide), CaO (calcium oxide), SrO (Strontium oxide), TiO (titanium monoxide), VO (vanadium monoxide), NbO (niobium monoxide), and the like.

The free layer 232, the tunnel barrier layer 233, and the fixed layer 234 may form an MTJ structure.

In addition to the MTJ structure, the variable resistance element 230 may further include layers having various purposes for improving the characteristics or process of the MTJ structure. For example, as illustrated in the embodiment illustrated in FIG. 2A, the lower layer 231, the magnetic compensation layer 235, and the capping layer 236 may be further included. However, according to other embodiments of the present disclosure, at least one of the lower layer 231 and the magnetic compensation layer 235 may be omitted, or additional layers that are not illustrated in FIG. 2A may be further included.

The lower layer 231 may include any constituent element of a variable resistance element that may improve diverse characteristics required for the MTJ structure below the MTJ structure. The lower layer 231 may have a single-layer structure or a multi-layer structure. For example, the lower layer 231 may function to improve the perpendicular magnetic anisotropy of the MTJ structure. The lower layer 231 may help to efficiently implant spin into the free layer 232, thereby improving the switching characteristics of the MTJ structure and contributing to increasing the magnetization stability of the free layer 232. The lower layer 231 may be distinguished from the lower contact plug 220 for electrically connecting the variable resistance element and the lower constituent elements to each other below the variable resistance element. According to the illustrated embodiment of the present disclosure, the lower layer 231 may be disposed over the first inter-layer dielectric layer 210, but if needed, in a variation of this embodiment, part or all of the lower layer 231 may be disposed over the lower contact plug 220 and buried in the first inter-layer dielectric layer 210 together with the lower contact plug 220.

The magnetic compensation layer 235 may function to offset or reduce the influence of the stray magnetic field that is formed by the fixed layer 234. In this case, the influence of the stray magnetic field of the fixed layer 234 on the free layer 232 may be reduced, thereby reducing a deflection magnetic field in the free layer 232. The magnetic compensation layer 235 may have a magnetization direction that is anti-parallel to the magnetization direction of the fixed layer 234. For example, when the fixed layer 234 has a magnetization direction that faces downward from the top, the magnetic compensation layer 235 may have a magnetization direction that faces upward from bottom. Conversely, when the fixed layer 234 has a magnetization direction from bottom to top, the magnetic compensation layer 235 may have a magnetization direction from top to bottom. The magnetic compensation layer 235 may reinforce the magnetization of the fixed layer 234 to help prevent the magnetization direction of the fixed layer 234 from changing due to an external magnetic field or temperature change, and may enhance the magnetic anisotropy of the fixed layer 234 to allow the fixed layer 234 to maintain a more stable magnetization state. The magnetic compensation layer 235 may have a single-layer structure or a multi-layer structure including a ferromagnetic material.

According to the illustrated embodiment of the present disclosure, the magnetic compensation layer 235 may exist over the fixed layer 234, but the position of the magnetic compensation layer 235 may be modified diversely. For example, the magnetic compensation layer 235 may be disposed below the MTJ structure. Also, for example, the magnetic compensation layer 235 may be patterned separately from the MTJ structure and disposed over, below, or alongside of the MTJ structure.

The capping layer 236 may function to couple the variable resistance element to the constituent elements over the variable resistance element, while protecting the layers disposed below the capping layer 236 during the patterning of the variable resistance element. To this end, the capping layer 236 may include a metal, which is a low-resistance material. The capping layer 236 may protect the MTJ structure from the external environment to prevent oxidation, thereby maintaining the lifespan and performance of the MTJ structure. For example, the capping layer 236 may include a noble metal which has a small number of pin holes in the layer and has a high resistance to wet and/or dry etching, such as ruthenium (Ru).

Subsequently, a bonding layer 237 may be formed over the uppermost layer of the first substrate 200, that is, over the capping layer 236. The bonding layer 237 may be provided for bonding the first substrate 200 and a second substrate 300, and may include a structure in which heterogeneous layers are stacked. The bonding layer 237 may include, for example, a stacked structure of a nitride layer and an oxide layer. The nitride layer may include, for example, a silicon nitride layer, and the oxide layer may include, for example, a silicon oxide layer. The bonding layer 237 may include silicon oxide, a polymer, a metal, or glass frit. In a specific embodiment, silicon oxide formed through a thermal oxidation process or a chemical deposition process may be used as the bonding layer, and in this case, the two substrates each with an oxide layer formed therein may be brought into contact followed by a heat treatment performed at a high temperature to form a chemical bond. Also, a polymer material such as, for example, benzocyclobutene (BCB) or an epoxy-based negative photoresist such as SU-8 may be used as the bonding layer, and the polymer bonding may enable bonding at a low temperature and provide flexible mechanical properties. Also, a metal bonding layer such as Au—Au bonding or Cu—Cu bonding may be used, and the metal layer may provide electrical conductivity and may be used for inter-layer connection in a three-dimensional (3D) integrated circuit. Also, the bonding layer may be formed by using glass frit having glass-like properties at a low temperature.

However, according to another embodiment of the present disclosure, the bonding layer 237 may be omitted. When there is no bonding layer 237, the surfaces of the two substrates may go through a chemical treatment for the two substrates to be directly bonded. For example, the two substrates may be bonded by a hydrophobic bonding method in which the substrate surfaces are bonded through a hydrogen bond.

Referring to FIG. 2B, a hard mask layer 340 for patterning the variable resistance element 230 may be formed over the second substrate 300. For example, the hard mask layer 340 may have an island shape in order to pattern the variable resistance element 230 in a pillar shape. The second substrate 300 may be a substrate which is obtained after a predetermined process. For example, the second substrate 300 may include a silicon substrate.

The hard mask layer 340 may include one or more selected from the group including polysilicon, metals, silicon germanium, and carbon. Preferably, the hard mask layer 340 may include at least one selected from the group including polysilicon and carbon. The hard mask layer 340 may include a material having an etching selectivity with respect to an etched layer, such as a variable resistance layer and a selection element unit SU. Since the hard mask layer 340 is formed not over the first substrate 200 where the variable resistance element 230 is formed but over the second substrate 300, it is possible to form a hard mask layer 340 having a high selectivity in an ion beam etching (IBE) process or a reactive ion etching (RIE) process through a high-temperature process exceeding approximately 300° C. In the process described below, when the variable resistance element 230 including the MTJ structure is etched through the IBE or RIE process, the high selectivity of the hard mask layer 340 may make it possible to form the variable resistance element 230 having a vertical profile.

In order to facilitate the separation of the second substrate 300 in the subsequent process, a separation layer 301 may be formed inside a desired depth of the second substrate 300 at a predetermined depth. The separation layer 301 may be formed by performing a hydrogen ion implantation process targeting a predetermined depth of the second substrate 300. A material such as silicon oxide (SiO₂) or silicon nitride (Si₃N₄) may be used as the separation layer 301, and this may be selectively removed through a chemical etching process, so that the bonded substrates may be separated, leaving only the remaining layer. A polymer material such as polyimide or SU-8 may be used as the separation layer 301, and this may be easily separated at a low temperature. Also, a tape that has a low adhesiveness and may be detached at a high temperature may be used as the separation layer 301, and when the bonded substrate is heated at a high temperature, the adhesive layer may become weak and be separated. Also, two substrates may be mechanically separated by interposing a layer having a weak mechanical bond between the two substrates without a separately provided separation layer 301 and applying an external force.

Referring to FIG. 2C, the first substrate 200 and the second substrate 300 may be bonded with each other by using the bonding layer 237 of the first substrate 200 and the hard mask layer 340 of the second substrate 300. The bonding of the first substrate 200 and the second substrate 300 may occur via either oxide-to-oxide bonding or Van der Waals force bonding. Also, the first substrate 200 and the second substrate 300 may be bonded by the electrical attraction between the two substrates which is caused by the charges remaining on the surfaces or the charges generated through a plasma treatment. Also, the bonding may be performed by the hydrogen bond that is formed on the silicon oxide surfaces of the two substrates, which provides a stronger bond than the Van der Waals force. A chemical reaction occurring during the bonding process may also enhance the bonding between the two substrates. For example, in a metal bonding, a strong metal bond may be formed as the metal ions are diffused and a chemical reaction occurs between the metal atoms. The bonding of these two substrates may be performed by a high-temperature bonding process or an ultrasonic bonding process. This may be mainly used for bonding silicon substrates or metal-to-metal bonding by placing the two substrates to face each other and applying high temperature and pressure to them. The ultrasonic bonding may be a method of bonding two substrates by using ultrasonic energy. During the ultrasonic bonding process, ultrasonic vibrations in the range of approximately 20 kHz to 60 kHz may be generally applied between the two substrates. This vibration may cause small friction on the surface of the substrate to form a bond.

### Referring to FIG. 2d, a Separation Process of the Second

substrate 300 where the bonding is completed may be performed. The separation process may be performed by grinding, polishing, or etching the upper surface of the second substrate 300. Also, when the separation layer 301 is formed in the second substrate 300 through a hydrogen ion implantation process, a grinding, polishing, or etching process may be performed until the separation layer is exposed. When the separation layer 301 is applied, an anisotropic or isotropic etching process may be performed after the separation layer 301 is exposed to planarize the remaining second substrate 300.

The hard mask layer 340 may be exposed on the uppermost layer of the structure which is obtained after the bonding process of the substrates and the separation process of the second substrate 300 are completed.

Referring to FIG. 2E, by etching the capping layer 236, the magnetic compensation layer 235, the fixed layer 234, the tunnel barrier layer 233, the free layer 232, and the lower layer 231 with the hard mask layer 340 used as an etching barrier, a variable resistance element 230 may be formed to have a vertical profile in which a lower layer pattern 231A, a free layer pattern 232A, a tunnel barrier layer pattern 233A, a fixed layer pattern 234A, a magnetic compensation layer pattern 235A, and a capping layer pattern 236A are stacked. Although not shown, a portion of the bonding layer pattern 237A and a portion of the hard mask pattern 340A may remain over the variable resistance element 230. This may be because the etching loading may vary according to the position of the variable resistance element 230.

When the hard mask layer 340 is formed over the variable resistance element 230 of one substrate and the variable resistance element 230 is patterned through an IBE process or an RIE process according to the prior art, the process may have to be performed at a low temperature of approximately 300° C. or lower in order to maintain the characteristics of the variable resistance element 230. Therefore, it is difficult to form a hard mask layer having a high IBE or RIE selectivity. However, since the variable resistance element 230 and the hard mask layer 340 are formed in the first substrate 200 and the second substrate 300 respectively and bonding and separation processes of the first substrate 200 and the second substrate 300 are performed, the hard mask layer 340 having a high IBE or RIE selectivity may be formed through a high-temperature process exceeding approximately 300° C. In the process of fabricating an electronic device including an MTJ structure, the problem of deteriorating operation characteristics that may occur when a high-temperature process is performed after MTJ deposition may be solved while securing a process margin at the same time by forming a hard mask layer through a high-temperature process exceeding approximately 300° C.

The electronic device as illustrated in FIG. 2E may be fabricated by the process described above.

Referring back to FIG. 2E, the electronic device in accordance with the embodiment of the present disclosure may include the lower contact plug 220 disposed over the first substrate 200 and coupled to a portion of the first substrate 200, the variable resistance element 230 disposed over the lower contact plug 220 and coupled to the lower contact plug 220, the remaining bonding layer pattern 237A (not shown), the hard mask pattern 340A (not shown), and the first inter-layer dielectric layer 210 surrounding the lower contact plug 220.

In the electronic device, the variable resistance element 230 may store data by switching between different resistance states according to the voltage or current applied to the lower and upper ends of the variable resistance element 230 through the lower contact plug 220 and the upper contact plug (not shown). For example, the data may be stored by changing the magnetization direction of the free layer pattern 232A according to the voltage or current applied to the variable resistance element 230. When the magnetization directions of the free layer pattern 232A and the fixed layer pattern 234A are parallel to each other, the variable resistance element 230 may be in a low resistance state and may store, for example, a data ‘1’. Conversely, when the magnetization directions of the free layer pattern 232A and the fixed layer pattern 234A are anti-parallel to each other, the variable resistance element 230 may be in a high resistance state and may store, for example, a data ‘0’.

According to the electronic device and the fabrication method thereof described above, when a variable resistance element and a hard mask layer are formed over one substrate, it is possible to realize a variable resistance element having an excellent vertical profile, which is difficult to obtain using existing methods. In particular, the hard mask formed through a high-temperature process may provide a high selectivity in the IBE or RIE process, so that it is possible to fabricate a high-density Magnetic Random Access Memory (MRAM) device while maintaining the characteristics of the MTJ structure even after the patterning process. This may significantly improve the performance of the MRAM element and the reliability of the fabrication process.

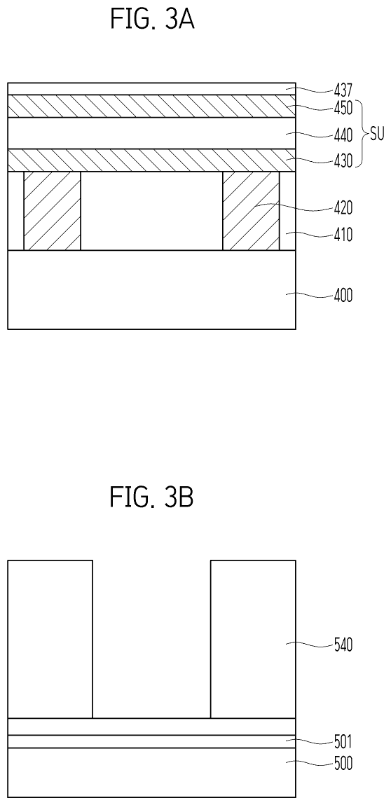

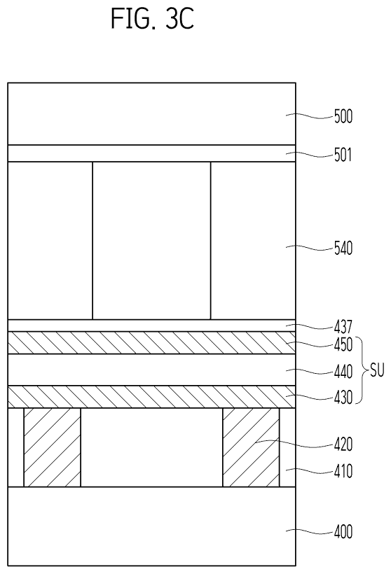

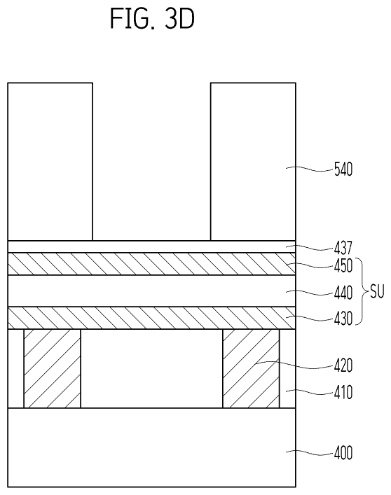

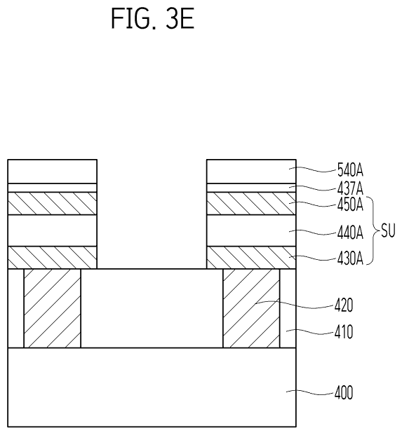

The above embodiment of the present disclosure describes patterning the variable resistance element 230 through the bonding and separation processes of the two substrates. This process may be used in all patterning processes using the IBE process, and may be used especially when a selection element is patterned. This method is described below by referring to FIGS. 3A to 3D. The description will focus on the differences from the above-described embodiments of the present disclosure.

Referring to FIG. 3A, a first inter-layer dielectric layer 410 and a lower contact plug 420 that passes through the first inter-layer dielectric layer 410 to be operatively coupled to a portion of the third substrate 400 may be formed over the third substrate 400.

Subsequently, a lower electrode layer 430 and a selection element layer 440 may be formed over the third substrate 400. The lower electrode layer 430 may be formed by depositing a conductive material. The selection element layer 440 may be formed by depositing a dielectric material layer over the lower electrode layer 430 followed by implanting a dopant into the dielectric material layer. The implantation of the dopant may be performed, for example, by an ion implantation method and may be performed toward the dielectric material layer in a direction perpendicular or substantially perpendicular to the surface of the third substrate 400. An intermediate electrode layer 450 may be formed over the selection element layer 440. The intermediate electrode layer 450 may be formed by a method of depositing a conductive material.

Referring to FIG. 3B, a hard mask layer 540 for patterning a selection element unit SU including the selection element layer 440 may be formed over fourth substrate 500. In order to facilitate separation of the fourth substrate 500 in a subsequent process, a separation layer 501 may be formed inside the fourth substrate 500 at a predetermined depth. As described above, a layer having a weak mechanical bond may be interposed between the two substrates without a separately provided separation layer 501 to mechanically separate the two substrates from each other by applying an external force.

Referring to FIG. 3C, the third substrate 400 and the fourth substrate 500 may be bonded together by using the bonding layer 437 of the third substrate 400 and the hard mask layer 540 of the fourth substrate 500.

Referring to FIG. 3D, after the bonding process, the separation process of the fourth substrate 500 is completed. The separation process may be performed by grinding, polishing, or etching the upper surface of the fourth substrate 500. Also, when the separation layer 501 is formed in the fourth substrate 500 through a hydrogen ion implantation process, the grinding, polishing, or etching process may be performed until the separation layer is exposed. When the separation layer 501 is applied, an anisotropic or isotropic etching process may be performed after the separation layer 501 is exposed to planarize the remaining fourth substrate 500.

The hard mask layer 540 may be exposed in the uppermost layer of the structure which is obtained after the bonding process of the substrate and the separation process of the fourth substrate 500 are completed.

Referring to FIG. 3E, a structure including the selection element having a vertical profile in which the lower electrode layer pattern 430A, the selection element layer pattern 440A, and the upper electrode layer pattern 450A are stacked, the remaining bonding layer pattern 437A, and the hard mask pattern 540A may be formed by using the hard mask layer 540 as an etching barrier and etching the lower electrode layer 430, the selection element layer 440, and the upper electrode layer 450.

The electronic device as illustrated in FIG. 3E may be fabricated by the process described above. According to the electronic device and the fabrication method thereof described above, it is possible to realize a selection element having an excellent vertical profile, which was difficult to obtain when the selection element and the hard mask layer are formed over one substrate. This makes it possible to realize a high-density integrated circuit by maximizing the space efficiency. Also, the selection element may be formed to have a clear and uniform boundary, minimizing leakage current. Furthermore, the inventive method may allow precise alignment between the layers in a multi-layer structure, thereby improving the performance and reliability of the various elements and of the overall device.

According to the embodiment of the present disclosure, the semiconductor device and a method for fabricating the same may solve the problem of deteriorating operation characteristics that may occur when a high-temperature process is performed after an MTJ is deposed while securing the process margin by forming a hard mask layer in a substrate where a Magnetic Tunnel Junction (MTJ) structure is formed and another substrate through a high-temperature process.

While the embodiments of the present disclosure have been described with respect to the specific embodiments, it will be apparent to those skilled in the art that various changes and modifications may be made without departing from the spirit and scope of the present disclosure as defined in the following claims. Furthermore, the embodiments may be combined to form additional embodiments.

What is claimed is:

1. An electronic device comprising:
an etched layer disposed over a substrate;
a hard mask pattern formed over the etched layer; and
a bonding layer pattern disposed between the etched layer and the hard mask pattern,
wherein the bonding layer pattern includes a dielectric material, and
wherein the hard mask pattern includes a material having an etching selectivity with respect to the etched layer.

2. The electronic device of claim 1, wherein the material of the hard mask pattern includes at least one selected from a group including polysilicon, metals, silicon germanium, and carbon.

3. The electronic device of claim 1, wherein the material of the hard mask pattern includes at least one selected from a group including polysilicon and carbon.

4. The electronic device of claim 1, wherein the etched layer includes,
a Magnetic Tunnel Junction (MTJ) structure including a free layer having a changeable magnetization direction, a fixed layer having a fixed magnetization direction, and a tunnel barrier layer interposed between the free layer and the fixed layer, and
a capping layer disposed over the MTJ structure and including a metal.

5. The electronic device of claim 4, wherein the etched layer further includes
a magnetic compensation layer which is disposed between the MTJ structure and the capping layer and offsets or reduces an influence of a stray magnetic field that is formed by the fixed layer.

6. The electronic device of claim 1, further comprising:
a dielectric layer suitable for protecting a surface of the etched layer.

7. The electronic device of claim 1, wherein the bonding layer pattern includes silicon oxide, a polymer, a metal, or glass frit.

8. The electronic device of claim 1, further comprising:
a selection element layer that controls access to the etched layer and has a vertical profile.

9. The electronic device of claim 1, wherein the etched layer is a variable resistance layer.

10. A method for fabricating an electronic device, the method comprising:
forming a material layer suitable for forming an etched layer over a first substrate;
forming a hard mask layer over a second substrate;
bonding the first substrate and the second substrate with each other in such a manner that the material layer and the hard mask layer face each other;
removing the second substrate from an upper portion of the hard mask layer; and
forming an etched layer pattern by performing an etching process with the hard mask layer used as an etching barrier.

11. The method of claim 10, wherein forming the material layer suitable for forming the etched layer over the first substrate includes:
forming a Magnetic Tunnel Junction (MTJ) structure including a free layer having a changeable magnetization direction, a fixed layer having a fixed magnetization direction, and a tunnel barrier layer interposed between the free layer and the fixed layer; and
forming a capping layer including a metal over the MTJ structure.

12. The method of claim 10, wherein the hard mask layer includes a material having an etching selectivity with respect to the etched layer pattern.

13. The method of claim 12, wherein the hard mask layer includes at least one selected from a group including polysilicon, metals, silicon germanium, and carbon.

14. The method of claim 12, wherein the hard mask layer includes at least one selected from a group including polysilicon and carbon.

15. The method of claim 10, wherein the etching process includes an ion beam etching (IBE) process or a reactive ion etching (RIE) process.

16. The method of claim 10, wherein bonding the first substrate and the second substrate includes a high-temperature bonding process or an ultrasonic bonding process.

17. The method of claim 10, further comprising:
forming a dielectric layer suitable for protecting a surface of the etched layer after the etching process for forming the etched layer pattern.

18. The method of claim 17, wherein forming the dielectric layer is performed by a chemical vapor deposition (CVD) or an atomic layer deposition (ALD) process.

19. The method of claim 10, wherein the etched layer is a variable resistance layer.

20. A method for fabricating an electronic device, the method comprising:
forming a material layer suitable for forming a selection element over a third substrate;
forming a hard mask layer over a fourth substrate;
bonding the third substrate and the fourth substrate with each other in such a manner that the material layer and the hard mask layer face each other;
removing the fourth substrate from an upper portion of the hard mask layer; and
forming a selection element pattern having a vertical profile by performing an etching process with the hard mask layer used as an etching barrier.

21. The method of claim 20, wherein the etching process includes an ion beam etching (IBE) process or a reactive ion etching (RIE) process.

22. The method of claim 20, wherein bonding the third substrate and the fourth substrate includes a high-temperature bonding process or an ultrasonic bonding process.
